(19) United States
(12) Patent Application Publication
(10) Pub. No.: US 2023/0156987 A1
(43) Pub. Date: May 18, 2023

(54) SIGNAL ISOLATION DEVICE AND METHOD FOR IMPROVING THE SAME

(71) Applicants: Inventec (Pudong) Technology Corporation, Shanghai (CN); INVENTEC CORPORATION, TAIPEI CITY (TW)

(72) Inventors: Hsin-Hung LIN, TAIPEI CITY (TW); Wei-Chen CHENG, TAIPEI CITY (TW)

(21) Appl. No.: 17/654,069

(22) Filed: Mar. 9, 2022

(30) Foreign Application Priority Data
Nov. 12, 2021 (CN) 202111336435.X

(51) Int. Cl. H05K 9/00; H05K 1/02

(52) U.S. Cl. CPC H05K 9/0086; H05K 1/0236; H01Q 1/50

(57) ABSTRACT

A signal isolation device includes at least one electromagnetic band-gap unit. The at least one electromagnetic band-gap unit includes a substrate, a metal foil main body, and a plurality of T-shaped metal foil features. The metal foil main body is disposed on the substrate, and the metal foil main body is square. The T-shaped metal foil features is disposed on the substrate and extending from a periphery of the metal foil main body. The T-shaped metal foil features are in a rotational symmetry around a center of the metal foil main body.

### CROSS-REFERENCE TO RELATED APPLICATION

This application claims priority to China Application Serial Number 202111336435.X, filed Nov. 12, 2021, which is herein incorporated by reference in its entirety.

### BACKGROUND

### Field of Invention

The present invention relates to a signal isolation device.

### Description of Related Art

Over the years, it has become more and more critical to curb high-frequency noises and improve the performance of RF antennas and RF circuits.

If the noise cannot be effectively curbed, the communication performance of the RF antennas and the RF circuits will be greatly reduced. There is no technology that can realize the anti-noise structure with a simple manufacturing process. The current anti-noise structure is mostly suitable for narrow frequency bands, so it cannot be effectively used in the antenna.

Recently, the demand for the Internet to replace traditional telephones has been increasing, and consumers have a significant demand for high-quality Internet-enabled devices. In addition, multi-band communication has been widely used in daily life.

Therefore, how to provide a signal isolation device that is small in size, simple in process, and widely used in multiple frequency bands has become a research target for private enterprises and academic institutions to invest a lot of money, manpower, and time.

### SUMMARY

The invention provides a method for improving a signal isolation device, including providing a signal isolation device which includes a plurality of electromagnetic band-gap (EBG) units adjoining each other, and each EBG unit has a substrate, a metal foil main body, and a plurality of metal features, the metal foil main body and the metal features are disposed on the substrate, and the metal feature extend from a periphery of the metal foil main body; generating a current concentration location related to the EBG units according to a corresponding frequency band of an insertion loss value of the signal isolation device; determining that the signal isolation device has a capacitive property or an inductive property according to the corresponding frequency band of the insertion loss value; and adjusting at least one of the metal features according to the current concentration location and according to the capacitive property or the inductive property of the signal isolation device.

In some embodiments of the present invention, the signal isolation device has the capacitive property, and adjusting the metal features includes adding a spiral path to one of the metal features.

In some embodiments of the present invention, the spiral path extends spirally from a center of the spiral path to an outward direction.

In some embodiments of the present invention, the signal isolation device has the inductive property, and adjusting the metal features includes adding an extension path, a portion of the extension path which is spaced apart from the metal foil main body extends along a periphery of the metal foil main body.

In some embodiments of the present invention, the portion of the extension path horizontally and straightly extends with respect to the periphery of the metal foil main body.

Another aspect of the present invention relates to a signal isolation device including at least one electromagnetic band-gap unit. The at least one electromagnetic band-gap unit includes a substrate, a metal foil main body, and a plurality of T-shaped metal foil features. The metal foil main body is disposed on the substrate, and the metal foil main body is square. The T-shaped metal foil features which are disposed on the substrate and extend from a periphery of the metal foil main body, wherein the T-shaped metal foil features are in a rotational symmetry around a center of the metal foil main body.

In some embodiments of the present invention, each T-shaped metal foil feature comprises a middle shaft portion, a first lateral portion, and a second lateral portion, wherein the middle shaft portion is disposed between the first lateral portion and the second lateral portion, the first lateral portion has a first length with respect to the middle shaft portion greater than a second length of the second lateral portion with respect to the middle shaft portion.

In some embodiments of the present invention, a ratio of the first length to a side length of the metal foil main body is between 0.45 and 0.58.

In some embodiments of the present invention, another ratio of the second length to the side length of the metal foil main body is between 0.1 and 0.3.

In some embodiments of the present invention, the substrate is square and has a side length ranging from about 7 mm to 25 mm.

In some embodiments of the present invention, the metal foil main body has a side length ranging from 5 mm to 20 mm.

In some embodiments of the present invention, the metal foil main body has a side length smaller than a side length of the substrate which is square.

In some embodiments of the present invention, the at least one electromagnetic band-gap unit includes a plurality of electromagnetic band-gap units which are arranged in a straight raw, one of the T-shaped metal foil features of one of the electromagnetic band-gap units joins one of the T-shaped metal foil features of another one of the electromagnetic band-gap units.

In some embodiments of the present invention, the at least one electromagnetic band-gap unit includes a plurality of electromagnetic band-gap units which are arranged in a straight raw, one of the T-shaped metal foil features of one of the electromagnetic band-gap units is in direct contact with one of the T-shaped metal foil features of another one of the electromagnetic band-gap units.

Another aspect of the present invention relates to a signal isolation device which includes a plurality of electromagnetic band-gap units arranged in a row, and each electromagnetic band-gap unit includes a square substrate, a square metal foil main body, and a plurality of T-shaped metal foil features. The square metal foil main body is disposed on the substrate. The plurality of T-shaped metal foil features are disposed on the substrate and extending from a periphery of the metal foil main body, and the T-shaped metal foil features are in a rotational symmetry around a center of the metal foil main body.

In some embodiments of the present invention, each T-shaped metal foil feature includes a middle shaft portion, a first lateral portion, and a second lateral portion, wherein the middle shaft portion is disposed between the first lateral portion and the second lateral portion, the first lateral portion has a first length with respect to the middle shaft portion greater than a second length of the second lateral portion with respect to the middle shaft portion.

In some embodiments of the present invention, a ratio of the first length to a side length of the metal foil main body is between 0.45 and 0.58.

In some embodiments of the present invention, another ratio of the second length to the side length of the metal foil main body is between 0.1 and 0.3.

In some embodiments of the present invention, the substrate has a side length ranging from about 7 mm to 25 mm.

In some embodiments of the present invention, the metal foil main body has a side length smaller than a side length of the substrate.

In embodiments of the present invention, a signal isolation device with electromagnetic band-gap units and a method for improving the same are provided, and the method can further improve the isolation abilities in the desired frequency bands. Therefore, the signal isolation device has outstanding isolation abilities in WiFi dual-bands and WiFi 6E bands.

It is to be understood that both the foregoing general description and the following detailed description are by examples, and are intended to provide further explanation of the invention as claimed.

### BRIEF DESCRIPTION OF THE DRAWINGS

The patent or application file contains at least one drawing executed in color. Copies of this patent or patent application publication with color drawing(s) will be provided by Office upon request and payment of the necessary fee. The disclosure can be more fully understood by reading the following detailed description of the embodiment, with reference made to the accompanying drawings as follows.

FIG. 1 illustrates a method for improving a signal isolation device in accordance with some embodiments of the present invention.

FIG. 2 illustrates a schematic view of a signal isolation device in accordance with some embodiments of the present invention.

FIG. 3 illustrates a comparison diagram of return loss of a signal isolation device in accordance with some embodiments of the present invention.

FIG. 4 illustrates a current distribution diagram of a signal isolation device in accordance with some embodiments of the present invention.

FIG. 5 illustrates a smith chart of a signal isolation device in accordance with some embodiments of the present invention.

FIG. 6 illustrates a top view of a signal isolation device in accordance with some embodiments of the present invention.

FIG. 7 illustrates a top view of a signal isolation device in accordance with some embodiments of the present invention.

FIG. 8 illustrates a schematic view of an electromagnetic band-gap unit in accordance with some embodiments of the present invention.

FIG. 9 illustrates a top view of an electromagnetic band-gap unit in accordance with some embodiments of the present invention.

FIG. 10 illustrates a comparison diagram of return loss of a signal isolation device in accordance with some embodiments of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

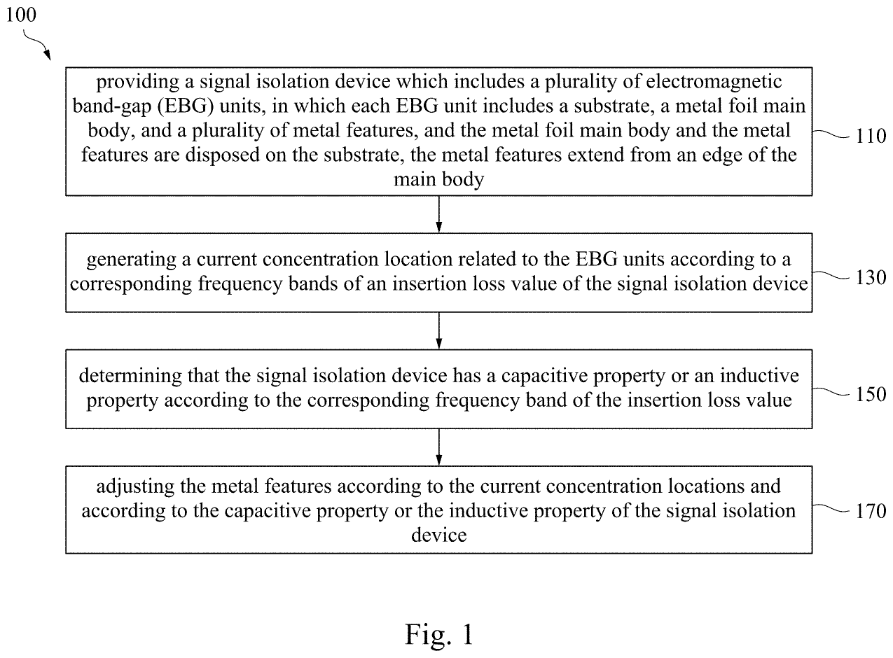

Reference is made to FIG. 1, which illustrates a method 100 for improving a signal isolation device. The method 100 starts from a step 110, which includes providing a signal isolation device, and the signal isolation device includes a plurality of electromagnetic band-gap (EBG) units adjoining each other. Each EBG unit includes a substrate, a metal foil main body, and a plurality of metal features, and the metal foil main body and the metal features are disposed on the substrate. The method 100 includes a step 130 which includes generating a current concentration location related to the EBG units according to a corresponding frequency band of an insertion loss value of the signal isolation device. The method 100 further includes a step 150 which includes determining that the signal isolation device has a capacitive property or an inductive property according to the corresponding frequency band of the insertion loss value. The method 100 further includes a step 170 which includes adjusting the metal features according to the current concentration location and according to the capacitive property or the inductive property of the signal isolation device. Therefore, the method 100 can efficiently decrease the insertion loss values related to the corresponding frequency band of the signal isolation device, so as to dramatically improve the isolation abilities of the corresponding frequency band of the signal isolation device.

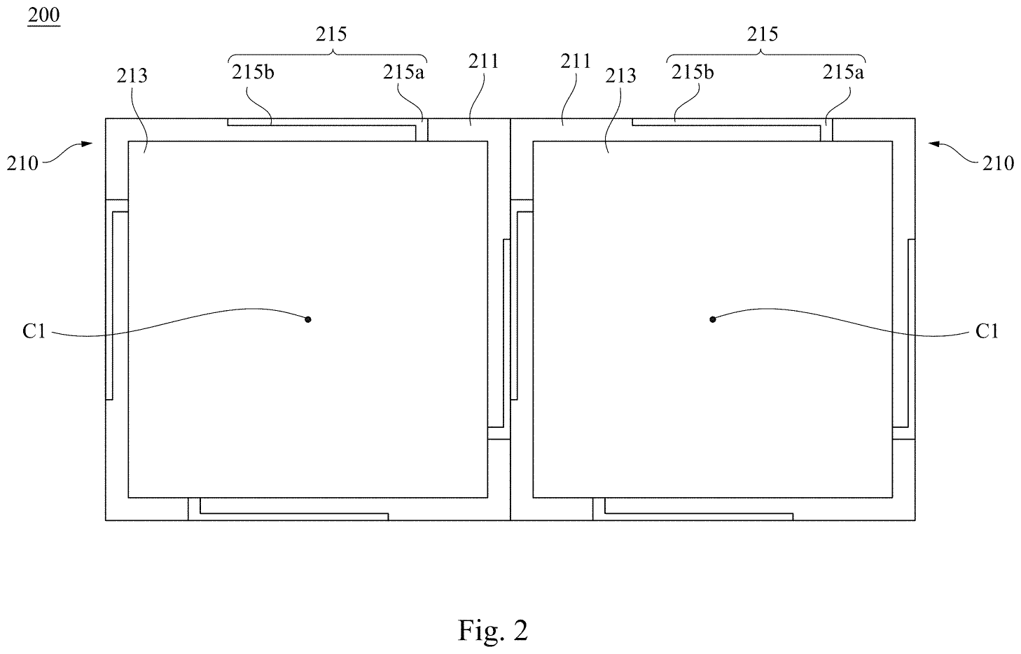

Reference is made to FIGS. 1-2, the step 110 includes providing the signal isolation device 200 which includes adjacent EBG units, and each EBG unit 210 includes a substrate 211, a metal foil main body 213, and a plurality of metal features 215. The metal foil main body 213 and the metal features 215 are located on the substrate 211, and the metal features 215 extend from a periphery of the metal foil main body 213. In addition, one of the metal features 215 of each EBG unit 210 joins another one of the metal features 215 of each EBG unit 210, so as to provide outstanding signal isolation ability. The one of the metal features 215 of each EBG unit 210 can be indirect contact with the another one of the metal features 215 of each EBG unit 210.

In some embodiments of the present invention, the metal foil main body 213 is square, and the metal features 215 is L-shaped. The metal features 215 respectively adjoin corners of the metal foil main body 213, and the metal features 215 are in a rotational symmetry around a center C1 of the metal foil main body 213. The center C1 can be a feeding point. In addition, the metal features 215 has a first extension portion 215a and a second extension portion 215b, and the first extension portion 215a directly joins the metal foil main body 213 and vertically extends with respect to a side of the square metal foil main body 213. The second extension portion 215b which horizontally extends with respect to the side of the square metal foil main body 213 is spaced apart from the side of the metal foil main body 213, and the first extension portion 215a is connected between the metal foil main body 213 and the second extension portion 215b. In addition, each EBG unit 210 further includes a flat metal foil which is disposed on a bottom surface of the substrate 211, but the present invention is not limited in this respect.

Specifically, the substrate 211 includes a single layer printed circuit board (PCB). For instance, the substrate 211 is a printed circuit board in FR4 printed circuit board specification, and the substrate 211 can be manufactured by laminating epoxy resin and woven glass. In addition, the metal foil main body 213 and the metal features 215 can be a continuous piece of material or not a continuous piece of material, and the metal foil main body 213 and the metal features 215 can include gold, silver, copper, stannum, plumbum, or alloy thereof. The metal foil main body 213 and the metal features 215 can be manufactured by a laser cutting process, an etching process, or a machining process. The present invention is not limited in this respect.

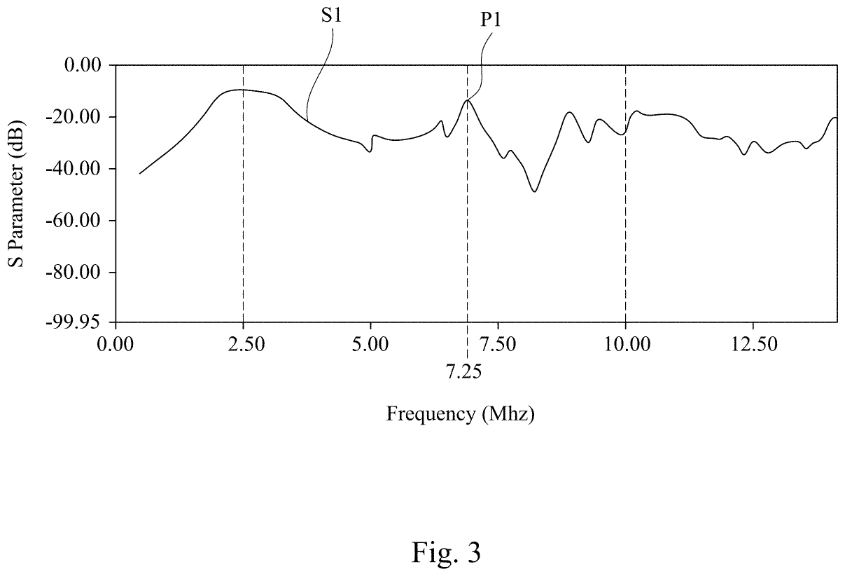

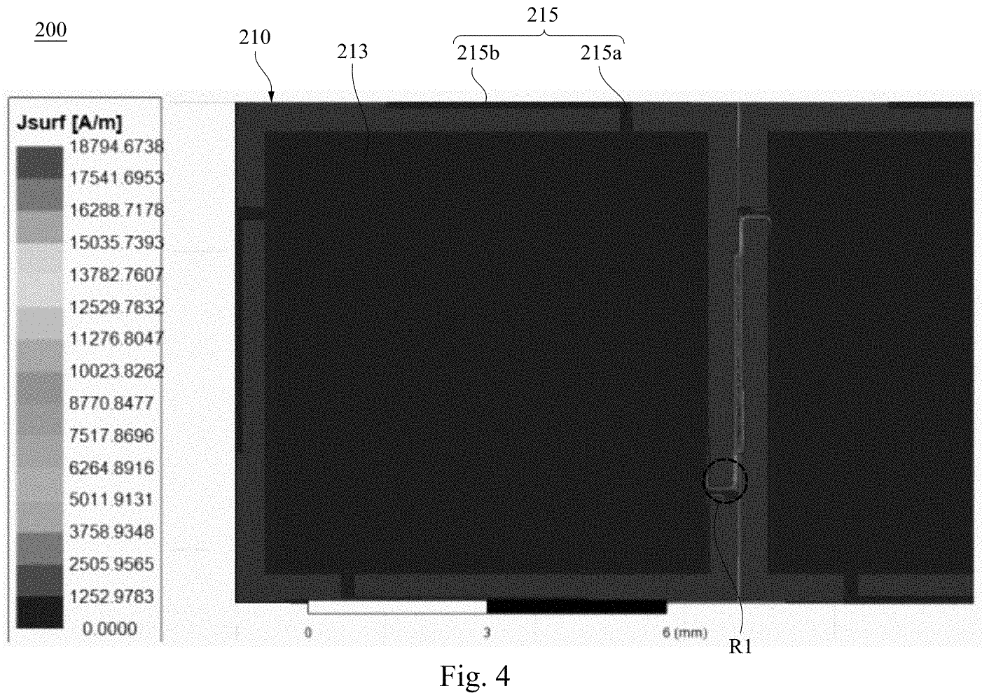

Reference is made to FIGS. 1-4. The step 130 includes generating a current concentration location related to the EBG units 210 according to a corresponding frequency band of the insertion loss value of the signal isolation device 200, and FIGS. 3-4 can represent the step 130. FIG. 3 illustrates a comparison diagram of return loss, and the curved line S1 in FIG. 3 at least shows insertion loss values of the signal isolation device 200 between 2 Mhz and 14 Mhz. FIG. 4 illustrates a current distribution diagram. The step 130 includes choosing an insertion loss value between 2 Mhz and 10 Mhz. For instance, the highest insertion loss value among insertion loss values in FIG. 3 can be chosen. In some embodiments of the present invention, the step 130 includes choosing a point P1 which represents the frequency band of 7.25 Mhz which is between 7 Mhz and 7.5 Mhz. The insertion loss value of the point P1 has an insertion loss value about −20 dB. In addition, an electromagnetic wave of about 7.25 Mhz is generated to pass through the signal isolation device 200. By measuring or simulating the current distribution diagram of the signal isolation device 200, a current concentration location R1 in FIG. 4 can be obtained. Specifically, electromagnetic simulation software such as High Frequency Structure Simulator (HFSS) and/or a magnetometer can be used to simulate FIG. 4. The present invention is not limited in this respect.

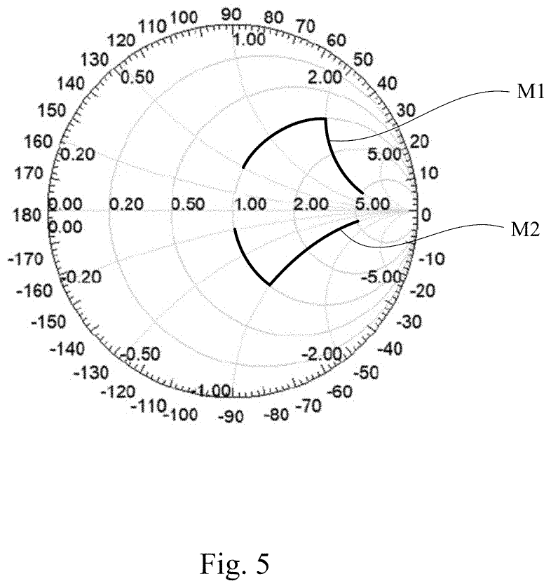

Reference is made to FIGS. 1 and 5. The step 150 includes determining that the signal isolation device 200 has a capacitive property or an inductive property according to the corresponding frequency band of the insertion loss value. For instance, the line M1 in FIG. 5, which is a smith chart, can represent the condition of the signal isolation device 200 measured or simulated in the corresponding frequency band. As known from the line M1, the signal isolation device 200 has the inductive property. In some other embodiments of the present invention, the line M2 in FIG. 5 can represent the signal isolation device 200 in different frequency bands and/or in different size from the line M1. As known from the line M2, the signal isolation device 200 has the capacitive property. For people who have general knowledge in the art, they well know the methods for measuring the signal isolation device 200 and illustrating the smith chart, and thus the detail information about measuring the signal isolation device 200 and illustrating the smith chart are neglected.

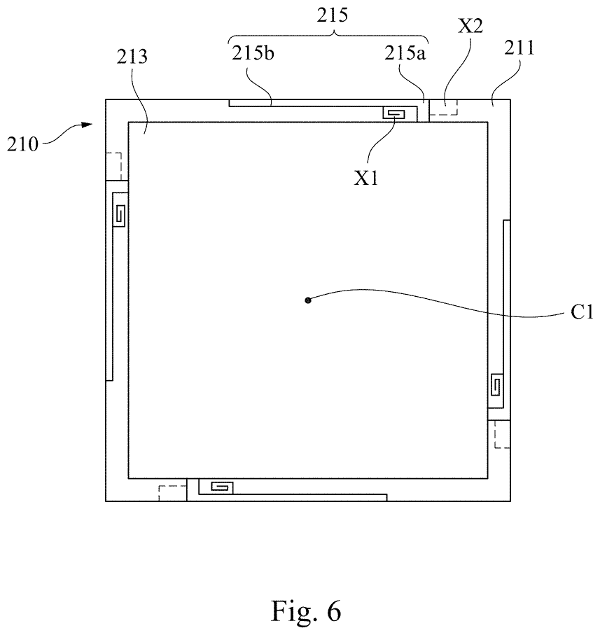

Reference is made to FIGS. 1, 4, and 6. In one or more embodiments of the present invention, the step 170 includes adjusting the metal features 215 according to the inductive property or the capacitive property of the signal isolation device 200 and the current concentration location R1. In FIG. 4, the current concentration location R1 immediately adjoins a junction between the first extension portion 215a and the second extension portion 215b, and the step 170 can includes adjusting the junction between the first extension portion 215a and the second extension portion 215b. In some embodiments of the present invention, when the signal isolation device 200 has the capacitive property, the step 170 includes adding a spiral path X1 to at least one of the metal features 215 around the current concentration location R1. Furthermore, additional spiral path X1 can be added to the other metal features 215 at corresponding positions such that all of the spiral paths and the meatal features are in a rotational symmetry around a center C1. The spiral path X1 extends from a center to an outward direction, and the spiral path X1 are made of metal, such as gold, silver, copper, stannum, plumbum, or alloy thereof. The present invention is not limited in this respect. Specifically, the spiral path X1 can be a rectangular spiral structure, and the spiral path X1 has portions which are vertical to or horizontal to an extension direction of the second extension portion 215b. The present invention is not limited in this respect. In some other embodiments of the present invention, the spiral path X1 can be a circular spiral structure or an ellipse spiral structure.

In some embodiments of the present invention, the step 170 includes that the signal isolation device 200 has the capacitive property. When the signal isolation device 200 has the capacitive property, the step 170 further includes adding an extension path X2 to at least one of the metal features 215 around the current concentration location R1. Furthermore, additional extension paths X2 can respectively be added to the other metal features 215 at corresponding positions, such that all the metal features and the extension paths are in a rotational symmetry around a center C1. The extension path X2 are made of metal, such as gold, silver, copper, stannum, plumbum, or alloy thereof, but the present invention is not limited in this respect. The extension path X2 has at least one portion which is spaced apart from the metal foil main body 213 and extends with respect to a periphery of the metal foil main body 213. In some embodiments of the present invention, the at least one portion of the extension path X2 extends straightly and extends horizontally with respect to the periphery of the metal foil main body 213, and the present invention is not limited in this respect.

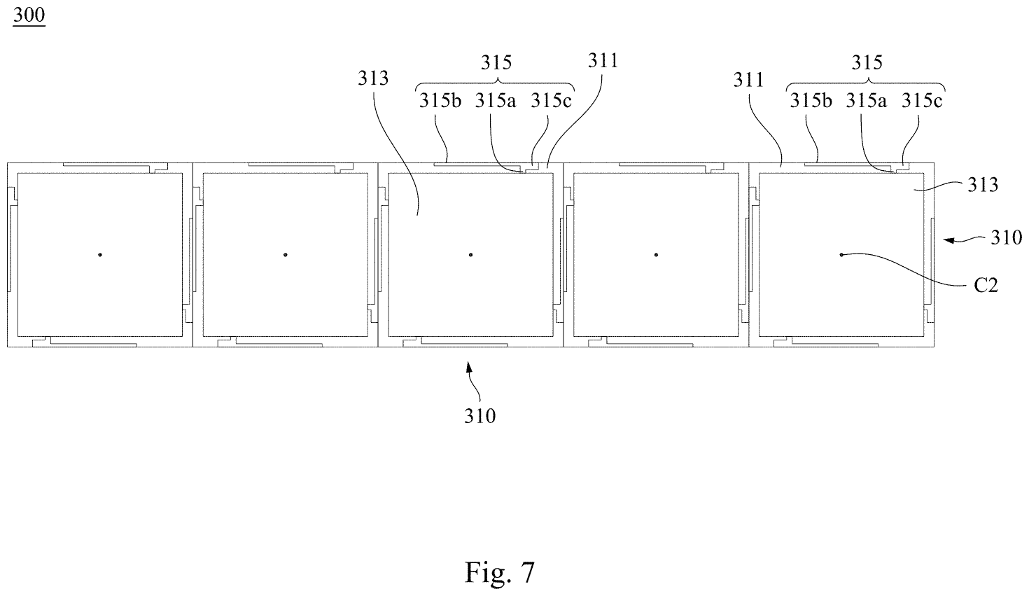

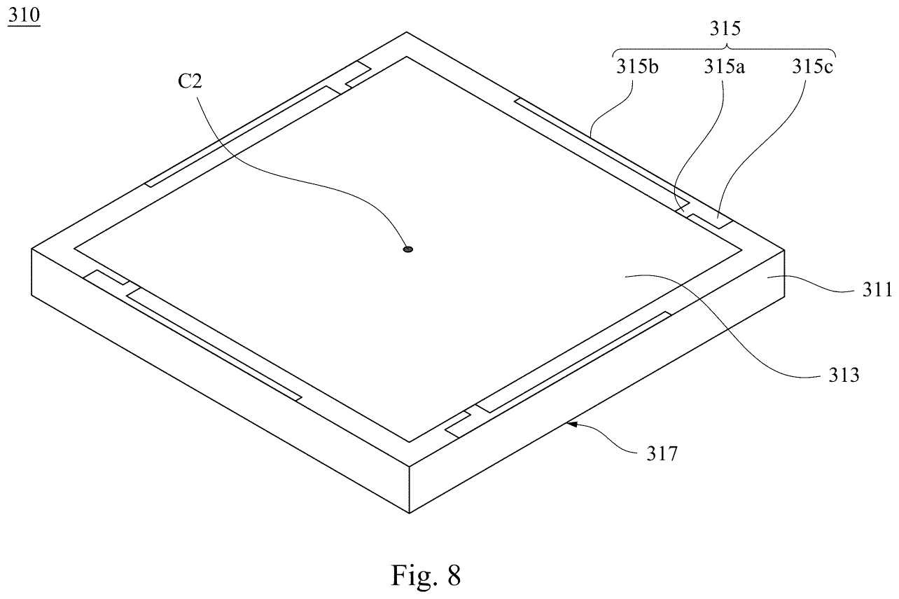

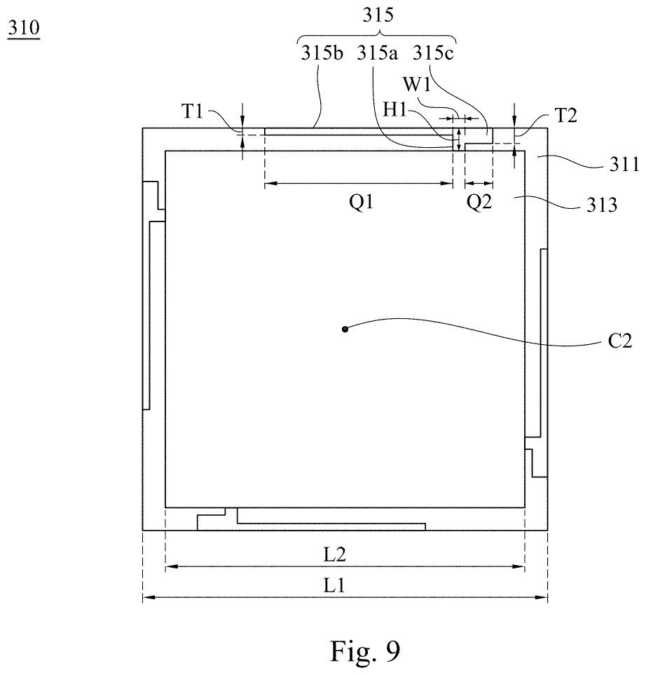

Reference is made to FIGS. 7-9. FIG. 7 illustrates a schematic view of a signal isolation device 300 which is manufactured by the method 100. FIG. 8 illustrates a schematic view of an EBG unit 310. FIG. 9 illustrates a top view of the EBG unit 310. In some embodiments of the present invention, the signal isolation device 300 includes at least one EBG unit 310 which has a substrate 311, a metal foil main body 313, and a plurality of T-shaped metal foil features 315. The metal foil main body 313 is located on the substrate 311, and the metal foil main body 313 is rectangular or square. The T-shaped metal foil features 315 which are located on the substrate 311 extend from sides of the metal foil main body 313 respectively, and the T-shaped metal foil features 315 is in a rotational symmetry around a center C2 of the metal foil main body 313, in which the center C2 can be a feeding point. In some embodiments of the present invention, the signal isolation device 300 includes a plurality of the EBG units 310 which are arranged along a straight row, and one of the T-shaped metal foil features 315 of one of the EBG units 310 joins or is in direct contact with one of the T-shaped metal foil features 315 of another one of the EBG units 310. The EBG units 310 are connected to each other for improving the signal isolation ability of the signal isolation device 300. In some embodiments of the present invention, the signal isolation device 300 further includes a flat metal foil 317 which is disposed on a bottom surface of the substrate 311, but the present invention is not limited in this respect.

Specifically, the substrate 311 can includes a single-layer printed circuit board. For instance, the substrate 311 is a printed circuit board in FR4 printed circuit board specification, and the substrate 311 can be manufactured by laminating epoxy resin and woven glass. In addition, the metal foil main body 313 and the T-shaped metal foil features 315 are a continuous piece of material or not a continuous piece of material, and the metal foil main body 313 and the T-shaped metal foil features 315 are made of gold, silver, copper, stannum, plumbum, or alloy thereof. The metal foil main body 313 and the T-shaped metal foil features 315 can be manufactured by a laser cutting process, an etching process, or a machining process. The present invention is not limited in this respect.

In some embodiments of the present invention, the substrate 311 is square, and the substrate 311 has a side length L1 ranging from about 7 mm to 25 mm. Preferably, the side length L1 of the substrate 311 ranges from about 8 mm to about 20 mm. For instance, the side length L1 of the substrate 311 is about 8.4 mm. In addition, the metal foil main body 313 is also square, and the metal foil main body 313 has a side length L2 smaller than the side length L1 of the substrate 311. The side length L2 of the metal foil main body 313 ranges from about 5 mm to 20 mm. Preferably, the side length L2 of the metal foil main body 313 ranges from about 6 mm to about 12 mm. For instance, the side length L1 of the substrate 311 is about 7.4 mm.

In some embodiments of the present invention, the T-shaped metal foil feature 315 extends from one side of the square metal foil main body 313, and the T-shaped metal foil features 315 includes a middle shaft portion 315a, a first lateral portion 315b, and a second lateral portion 315c. The first lateral portion 315b and the second lateral portion 315c are substantially rectangular, and the middle shaft portion 315a is located between the first lateral portion 315b and the second lateral portion 315c. The first lateral portion 315b and the second lateral portion 315c respectively extend along two opposite directions and horizontally extend with respect to the side of the metal foil main body 313. In addition, the first lateral portion 315b has a first length Q1 with respect to the middle shaft portion 315a greater than a second length Q2 of the second lateral portion 315c with respect to the middle shaft portion 315a, and the first length Q1 and the second length Q2 is measured along a direction parallel to the aforementioned side of the metal foil main body 313.

In some embodiments of the present invention, a ratio of the first length Q1 to the side length L2 of the metal foil main body 313 is between 0.45 and 0.58. When the ratio of the first length Q1 to side length L2 of the metal foil main body 313 is between 0.45 and 0.58, the signal isolation device 300 has outstanding signal isolation abilities. In some embodiments of the present invention, a ratio of the second length Q2 to the side length L2 of the metal foil main body is between 0.1 and 0.3. When the ratio of the second length Q2 to the side length L2 of the metal foil main body is between 0.1 and 0.3, the signal isolation device 300 has outstanding signal isolation abilities. The present invention is not limited in this respect.

In some embodiments of the present invention, the first lateral portion 315b has a first width T1 with respect to the corresponding side of the metal foil main body 313, and the first width T1 is smaller than a second width T2 of the second lateral portion 315c with respect to the corresponding side of the metal foil main body 313. The first width T1 and the second width T2 are measured along a direction vertical to the corresponding side of the metal foil main body 313. Specifically, a ratio of the first width T1 to the second length L2 of the metal foil main body 313 is between 0.0125 and 0.05, and a ratio of the second width T2 to second length L2 of the metal foil main body 313 is between 0.02 and 0.05 such that the signal isolation device 300 has outstanding signal isolation abilities.

In one or more embodiments of the present invention, the middle shaft portion 315a which is rectangular extends away from the metal foil main body 313, and the middle shaft portion 315a has a height H1 with respect to the metal foil main body 313, in which the height H1 is between 0.4 mm and 0.6 mm. For instance, the height H1 of the metal foil main body 313 is 0.5 mm. In addition, the middle shaft portion 315a has a width W1 between 0.15 mm and 0.25 mm. For instance, the width W1 of the middle shaft portion 315a is 0.2 mm. The present invention is not limited in this respect.

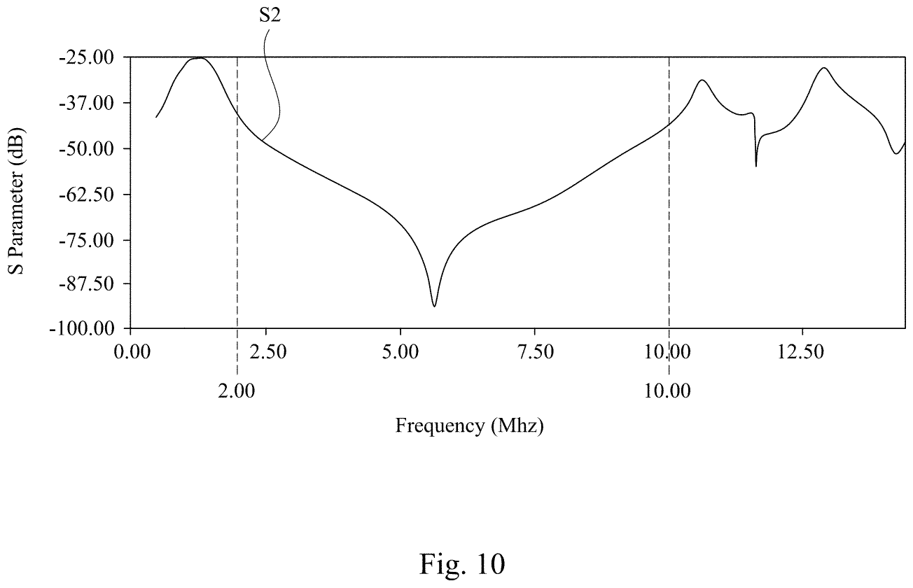

Please refer to FIG. 10, which illustrates a comparison diagram of return loss, and the curved line S2 in FIG. 10 represents return loss values of the signal isolation device 300. As known from FIG. 10, the return loss values of the signal isolation device 300 are smaller than −40 dB regarding the frequency bands from 2 Mhz to 10 Mhz, and thus the signal isolation device 300 can efficiently cover WiFi dual-bands and WiFi 6E bands which are from 2.4 GHz to 7.125 GHz, so as to provide excellent signal isolation abilities in these band ranges.

In embodiments of the present invention, a signal isolation device with electromagnetic band-gap units and a method for improving the same are provided, and the method can further improve the isolation abilities in the desired frequency bands. Therefore, the signal isolation device has outstanding isolation abilities in WiFi dual-bands and WiFi 6E bands.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method for improving a signal isolation device, comprising:
providing a signal isolation device which includes a plurality of electromagnetic band-gap (EBG) units adjoining each other, and each EBG unit has a substrate, a metal foil main body, and a plurality of metal features, the metal foil main body and the metal features are disposed on the substrate, and the metal features extend from a periphery of the metal foil main body;
generating a current concentration location related to the EBG units according to a corresponding frequency band of an insertion loss value of the signal isolation device;
determining that the signal isolation device has a capacitive property or an inductive property according to the corresponding frequency band of the insertion loss value; and
adjusting at least one of the metal features according to the current concentration location and according to the capacitive property or the inductive property of the signal isolation device.

2. The method of claim 1, wherein the signal isolation device has the capacitive property, and adjusting the metal features includes adding a spiral path to one of the metal features.

3. The method of claim 2, wherein the spiral path extends spirally from a center of the spiral path to an outward direction.

4. The method of claim 1, wherein the signal isolation device has the inductive property, and adjusting the metal features includes adding an extension path, a portion of the extension path which is spaced apart from the metal foil main body extends along a periphery of the metal foil main body.

5. The method of claim 4, wherein the portion of the extension path horizontally and straightly extends with respect to the periphery of the metal foil main body.

6. A signal isolation device, comprising:
at least one electromagnetic band-gap unit, comprising:
a substrate;
a metal foil main body disposed on the substrate, and the metal foil main body is square; and
a plurality of T-shaped metal foil features disposed on the substrate and extending from a periphery of the metal foil main body, wherein the T-shaped metal foil features are in a rotational symmetry around a center of the metal foil main body.

7. The signal isolation device of claim 6, wherein each T-shaped metal foil feature comprises a middle shaft portion, a first lateral portion, and a second lateral portion, wherein the middle shaft portion is disposed between the first lateral portion and the second lateral portion, the first lateral portion has a first length with respect to the middle shaft portion greater than a second length of the second lateral portion with respect to the middle shaft portion.

8. The signal isolation device of claim 7, wherein a ratio of the first length to a side length of the metal foil main body is between 0.45 and 0.58.

9. The signal isolation device of claim 8, wherein another ratio of the second length to the side length of the metal foil main body is between 0.1 and 0.3.

10. The signal isolation device of claim 6, wherein the substrate is square and has a side length ranging from 7 mm to 25 mm.

11. The signal isolation device of claim 6, wherein the metal foil main body has a side length ranging from 5 mm to 20 mm.

12. The signal isolation device of claim 6, wherein the metal foil main body has a side length smaller than a side length of the substrate which is square.

13. The signal isolation device of claim 6, wherein the at least one electromagnetic band-gap unit comprises a plurality of electromagnetic band-gap units which are arranged in a straight raw, one of the T-shaped metal foil features of one of the electromagnetic band-gap units joins one of the T-shaped metal foil features of another one of the electromagnetic band-gap units.

14. The signal isolation device of claim 6, wherein the at least one electromagnetic band-gap unit comprises a plurality of electromagnetic band-gap units which are arranged in a straight raw, one of the T-shaped metal foil features of one of the electromagnetic band-gap units is in direct contact with one of the T-shaped metal foil features of another one of the electromagnetic band-gap units.

15. A signal isolation device, comprising:
a plurality of electromagnetic band-gap units arranged in a row, and each electromagnetic band-gap unit comprising:
a square substrate;
a square metal foil main body disposed on the substrate; and
a plurality of T-shaped metal foil features disposed on the substrate and extending from a periphery of the metal foil main body, wherein the T-shaped metal foil features are in a rotational symmetry around a center of the metal foil main body.

16. The signal isolation device of claim 15, wherein each T-shaped metal foil feature comprises a middle shaft portion, a first lateral portion, and a second lateral portion, wherein the middle shaft portion is disposed between the first lateral portion and the second lateral portion, the first lateral portion has a first length with respect to the middle shaft portion greater than a second length of the second lateral portion with respect to the middle shaft portion.

17. The signal isolation device of claim 16, wherein a ratio of the first length to a side length of the metal foil main body is between 0.45 and 0.58.

18. The signal isolation device of claim 17, wherein another ratio of the second length to the side length of the metal foil main body is between 0.1 and 0.3.

19. The signal isolation device of claim 15, wherein the substrate has a side length ranging from 7 mm to 25 mm.

20. The signal isolation device of claim 15, wherein the metal foil main body has a side length smaller than a side length of the substrate.
